(19) United States
(12) Patent Application Publication
(10) Pub. No.: US 2026/0343811 A1
(43) Pub. Date: Oct. 29, 2026

(54) COOLING OF ELECTRONIC COMPONENTS

(71) Applicant: Schlumberger Technology Corporation, Sugar Land, TX (US)

(72) Inventors: Andrew Clarke, Cambridge (GB); Mahdi Davoodi, Cambridge (GB); John Morrison Whyte, Cambridge (GB); Joshua Damian Knowles, Cambridge (GB)

(21) Appl. No.: 19/311,001

(22) Filed: Aug. 27, 2025

(30) Foreign Application Priority Data
Apr. 28, 2025 (GB) 2506415.5

(51) Int. Cl. H05K 7/20; G06F 1/20

(52) U.S. Cl. CPC H05K 7/20272; G06F 1/20; H05K 7/20236; H05K 7/20772; G06F 2200/201; H05K 7/20281

(57) ABSTRACT

Cooling of electronic equipment, e.g. a server in a data center, uses a coolant liquid which runs through a hollow vessel in thermal contact with a heat-emitting electronic component or through a container within which heat-emitting electronic component(s) are immersed in the circulating coolant liquid. Elastic turbulence is induced in the flow over the heat-emitting electronic component(s) to enhance heat transfer to the coolant liquid. The coolant may contain suspended particles which melt during flow over the heat-emitting components, enhancing the heat carrying capacity of the liquid.

### CROSS REFERENCE TO RELATED APPLICATIONS

This application claims priority to GB Patent Application No.: 2506415.5, which was filed on Apr. 28, 2025, and is incorporated herein by reference in its entirety.

### FIELD

This disclosure relates to cooling of electronic components and circuit boards carrying electronic components. It may be used for cooling in data centers.

### BACKGROUND

A data center typically contains numerous racks of circuit boards on which there are electronic components which produce heat as they operate. Consequently, it is conventional that a data center has a system for cooling these components during operation. Such systems may transfer the heat to a larger cooling system which may in turn transfer the heat to the environment outside the building.

There are a number of methods for cooling circuit boards or individual components of those boards. One possibility is a system of forced air cooling. However, when the heat output is large, liquid cooling may be used. One system for liquid cooling circulates the cooling liquid through a vessel referred to as a “cold plate” which is mounted on top of a heat generating component such as a CPU or a GPU. This vessel acts as a heat sink and it may have a large number of internal fins so as to transfer heat from the electronic component to liquid flowing over these fins. Such an arrangement has been termed “direct liquid cooling” although that name has not been used consistently.

Another possibility which may be used when the heat output is very large is to use a circulating liquid which is not electrically conducting, referred to as a “dielectric fluid” and immerse the heat emitting component, or at least part of the circuit board to which the component is attached, in the dielectric fluid. This arrangement has been referred to as “total liquid cooling” or “immersion cooling”.

To enable immersion cooling, circuit boards with electronic components on them are partially or wholly immersed within tanks of the dielectric fluid, which requires the supporting racks and/or the building structure to be more strongly constructed in order to carry the weight of the tanks of dielectric fluid.

### SUMMARY

This summary is provided to introduce concepts that will be further elaborated and described below in the detailed description. This summary is not intended to identify key or essential features of the claimed subject matter, nor is it intended to be used as an aid in limiting the scope of the claimed subject matter.

This disclosure uses the phenomenon of elastic turbulence which was discovered during the latter part of the twentieth century. It occurs at a flow rate where a Newtonian liquid such as pure water would be in a state of laminar flow.

In a first aspect, this disclosure relates to computing equipment comprising one or more circuit boards with one or more heat-emitting electronic components attached thereto together with a cooling system for the one or more components, where the cooling system comprises: a flow circuit for coolant liquid together with at least one pump to propel coolant liquid around the circuit, where the path of liquid flow runs either (a) through a hollow vessel in thermal contact with the one or more components or (b) through a container within which the one or more electronic components are immersed in the circulating coolant liquid, wherein the coolant liquid contains, in solution therein, a substance enabling the liquid to undergo elastic turbulence and the path of liquid flow through the vessel or in contact with the one or more electronic components is configured to compel the flowing liquid to make repeated changes in direction.

Space within the vessel or adjacent to the electronic components may contain obstructions which compel the flow to curve rather than flowing in a straight line. The obstructions may compel the flow to make repeated changes of direction, so that there is curvature of the flow at each change of direction.

A second aspect of this disclosure is a method of cooling one or more heat-emitting electronic components attached to one or more circuit boards, comprising: circulating a coolant liquid through a hollow vessel in thermal contact with the one or more components, or through a container within which the one or more electronic components are immersed in the circulating coolant liquid, wherein: the path of liquid flow through the hollow vessel or in contact with the one or more electronic components is configured to compel the direction of flow of the liquid to curve by compelling the liquid flow to make repeated changes in direction within the vessel or adjacent to the immersed electronic components, the coolant liquid contains, in solution therein, a substance enabling the liquid to undergo elastic turbulence, and the rate of flow of the coolant liquid through the hollow vessel or adjacent to the electronic components is such that the flowing coolant liquid is in a state of elastic turbulence within the vessel or in contact with the one or more components.

Elastic turbulence will assist the transfer of heat energy into the coolant liquid by mixing the coolant as it travels. Inertial turbulence would consume more input power because it would require more flow speed and pumping power. Also elastic turbulence has a constrained frequency spectrum compared to inertial turbulence and so will generate less mechanical stress on components on the printed circuit boards.

In the present disclosure, the circulating liquid may also contain a substance which has little or no solubility in the liquid and has a melting temperature such that the substance is melted by heat from an electronic component as the substance flows over the component or through the vessel, so that the melting temperature is between the temperatures at the inlet and outlet of the vessel. This change of phase from solid to liquid will enhance the cooling effect because heat energy emitted from the electronic component will provide the latent heat required to melt the substance as well as the heat to increase the temperature of the flowing fluid. This substance may be particles suspended or emulsified in the circulating liquid. Using a phase change material in combination with elastic turbulence has the benefit that the elastic turbulence will carry the phase change material to and from the surfaces of electronic components to be cooled and in this way enhance the transfer of heat energy from the components, compared to a phase change material carried in a laminar flow of liquid.

### BRIEF DESCRIPTION OF THE DRAWINGS

FIG. 1 is a schematic cross section of a data center building.

FIG. 2 is a schematic cross section of a computing device on line Y-Y of FIG. 3.

FIG. 3 is a cross section on line X-X of FIG. 2.

FIG. 4 is a cross section of a hollow vessel for through flow of coolant liquid.

FIG. 5 is a cross section of the same hollow vessel on the line Z-Z of FIG. 4.

FIG. 6 is an enlarged cross-section in the same plane as FIG. 4.

FIG. 7 is a cross section of another hollow vessel.

FIG. 8 is a schematic sectional view of a coolant bath on line B-B of FIG. 1.

FIG. 9 is a schematic sectional view of the coolant bath on line C-C of FIG. 8.

FIG. 10 is a cross section of the coolant bath and associated heat exchanger.

FIG. 11 is a cross section of the computing device shown in FIG. 10 on the line D-D of FIG. 10.

FIG. 12 is a cross section of another computing device.

### DETAILED DESCRIPTION

This detailed description shows various embodiments of the present disclosure and possibilities which may be used. These are given as examples and do not limit this disclosure as defined by the claims. It should be appreciated that features or possibilities described in combination may, where it is practical to do so, be used separately. Also, features or possibilities described in any embodiment may be used in any other embodiment, in so far as it is possible to do so.

The present disclosure uses the phenomenon of elastic turbulence. It is of course well known that Newtonian liquids such as pure water can undergo either laminar flow or turbulent flow. Such turbulent flow may be referred to as inertial turbulence. Inertial turbulence within a pipe or other structure occurs at a higher speed of flow than laminar flow in the same pipe or structure. Conditions for laminar flow and inertial turbulent flow are often expressed by Reynolds number which is a ratio of inertial to viscous forces within a liquid. Reynolds number has no dimensions because it is a ratio. At Reynolds number above about 2000 there is inertial turbulent flow. At Reynolds number below about 1500, flow of a Newtonian liquid is laminar.

Elastic turbulence is different from inertial turbulence. It is a physical phenomenon discovered during the later part of the twentieth century. It has been observed at low flow speeds where Reynolds number is low and a Newtonian liquid would be in a state of laminar flow. Some early observations of elastic turbulence used the older term “elastic instability”. However, that term is more general and includes other forms of instability in flow. Literature documents relating to elastic turbulence include a detailed discussion by Steinberg in Annual Review of Fluid Mechanics, vol 53, pages 27-58 (2021).

Elastic turbulence occurs in solutions containing a solute which has a flexible structure. One category of material able to undergo elastic deformation and enable a solution to display elastic turbulence is a polymer containing long flexible linear chains. The number of monomer units in the polymer may be at least 5000 and may be considerably more such as at least 25,000. The monomer units may be present in linear chains of at least 1000 monomer units which may each be connected one to the next by a single covalent bond, so that one monomer unit can rotate relative to adjoining monomer units. Individual linear chains may be longer and a polymer may contain a linear chain of at least 5000 or even at least 10,000 monomer units. A polymer chain may contain only one kind of monomer or the chain may be a copolymer of more than one monomer, for instance a block copolymer which is linear. A polymer may also include side chains attached to a long chain of monomer units which are connected together by single covalent bonds. If a chain contains units which are themselves an oligomer, as in a block copolymer for instance, the oligomeric units may rotate relative to one another more freely than monomer residues within an oligomeric unit. A polymer may include some chain branching, for instance at branch points where three or more linear chains, each of at least 1000 monomer units, are connected together. When using a long chain polymer to enable elastic turbulence to occur, it is desirable to include a biocide to protect the long chain linear polymer from biodegradation.

The flexibility of the polymer chains enables the polymer molecules to become entangled. The flexibility of polymer chains can be described by means of a mathematical model. The freely jointed chain model is commonly used and the flexibility of a particular polymer can be indicated by parameters of an equivalent freely jointed chain (itself a mathematical model). A description of this approach is provided by Chapter 2 of “Polymer Physics” by Rubinstein and Colby, 2003, Oxford University Press. An equivalent freely jointed chain has the same mean-square end-to-end distance and the same maximum end-to-end distance as the actual polymer but is considered to consist of so-called Kuhn monomers which are freely rotatable relative to each other. These model monomers have a length, termed the Kuhn length, and a molar mass.

Polymers to enable elastic turbulence may contain at least one flexible polymer chain with length and composition represented by at least 5000 Kuhn monomers having a Kuhn length not more than 100 Angstroms (10 nm) and possibly not more than 50 Angstroms. If a polymer is a single unbranched chain, its length and composition may correspond to at least 20,000 Kuhn monomers and possibly at least 50,000 Kuhn monomers.

The mean molecular weight of the polymer may be at least one Mega Dalton i.e. at least 10⁶ Daltons, possibly at least 10 Mega Daltons or more. The concentration of such long chain/high molecular weight polymer included in a solution for enabling elastic turbulence to occur may be under 5% by weight, for instance in a range from 0.05% or 0.1% up to 1% or 2% by weight.

Elastic turbulence has been observed with several different long chain polymers in solution. One such polymer is polyacrylamide, which may be hydrolysed or partially hydrolysed. Experimental evidence for elastic turbulence in a solution of high molecular weight polyacrylamide was given by Groisman and Steinberg in “Elastic Turbulence in a polymer solution flow” Nature, Vol 45 p 53 (2000). Other instances of long chain polymers reported to give rise to elastic turbulence include polyisobutylene of molecular weight 4 to 6 Megadaltons dissolved in an organic solvent (Dris and Shaqfeh, J. Non-Newtonian Fluid Mech. Vol 80 pages 1 to 58 (1998)), polystyrene of molecular weight 18 Megadaltons in an organic solvent (Magda and Larson, J. Non-Newtonian Fluid Mech. Vol 32 pages 1-19 (1988)) and polyethylene oxide of molecular weight 4 MegaDaltons in an aqueous solution (Davoodi et al, J. Fluid Mech. Vol 857, pages 823-850 (2018)). Kuhn lengths for polystyrene and polyethylene oxide given by Rubinstein and Colby, page 53 are 18 Angstroms and 11 Angstroms. Kuhn length for polyacrylamides has been reported as 15 to 25 Angstroms (Fetters, Lohse and Colby, Chain Dimensions and Entanglement Spacings. In Physical Properties of Polymers Handbook; Mark, J. E., Ed.; Springer: New York, 2007; pages 447-454).

Long chain partially hydrolysed polyacrylamide linear polymers with a molecular weight of more than 1 MegaDalton are available from SNF Floerger, whose headquarters are in Andrézieux, France.

Another category of material which is able to undergo elastic deformation and enable a solution to display elastic turbulence is a viscoelastic surfactant which forms worm-like micelles in solution. Such micelles have also been referred to as “rod-like”. Scientific literature concerning surfactants which form worm-like micelles, their properties and applications includes a review by Yang “Viscoelastic wormlike micelles and their applications” Current Opinion in Colloid & Interface Science vol 7 pages 276_281 (2002). Discussions of properties include Raghavan and Kaler “Highly Viscoelastic Wormlike Micellar Solutions Formed by Cationic Surfactants with Long Unsaturated Tails” Langmuir vol 22, pages 324-326 (2401) and Beaumont et al “Turbulent flows in highly elastic wormlike micelles” Soft Matter vol 9 page 735 (2413).

A number of viscoelastic surfactants which spontaneously form wormlike micelles in aqueous solution are set out in T. Saeki “Flow properties and heat transfer of drag reducing surfactant solutions” which is chapter 18 of “Developments in Heat Transfer” edited by D. M. A. D. S. Bernardes, published by InTechOpen, 2411. One possibility mentioned there is cetyl-trimethyl-ammonium chloride in a solution also containing sodium salicylate. Another possibility is stearyl-trimethyl-ammonium chloride which is effective in reducing drag at temperatures up to and above 100 °C. A suitable concentration of a viscoelastic surfactant to form wormlike micelles may be 10 gm/litre or less, possibly from 1 to 10 or 1 to 5 gm/litre. Such a compound may have a molecular weight not greater than 1000 Daltons.

The compound 2,4-bis(2-ethylhexylureido) toluene (EHUT) has also been found to form extended worm-like aggregate structures in hydrocarbon solvents, as described by Burger et al in “Complete Dynamic Phase Diagram of a Supramolecular Polymer” Macromolecules vol 55 pages 2609-2614 (2022).

When a solution contains a substance able to cause elastic turbulence, the phenomenon of elastic turbulence occurs if the solution is flowing at a sufficient flow velocity (which may be a low velocity and below velocities at which there is inertial turbulence) and the path of flow causes the streamlines of the flow to make a succession of changes of direction, thereby causing the direction of flow to curve. The changes in direction may be continuous curvature as in concentric or helical flow or may alternate between turning to the right and to the left. Consequently, one known possibility for a flow path which induces elastic turbulence is a serpentine channel. Another possibility is a flow path with obstructions which compel the streamlines of flow to change direction. Such obstructions may be manufactured and arranged in a pattern so as to compel flow around the obstructions to change direction.

To summarise: the phenomenon of elastic turbulence of a liquid requires:
(i) a solute whose dissolved form has sufficient length to have elastic properties, enabling the liquid solution to display elastic turbulence,
(ii) a flow path for the liquid which compels a succession of changes in its direction of flow, and
(iii) pumping the liquid along the flow path at a sufficient velocity, but below velocities at which inertial turbulence occurs.

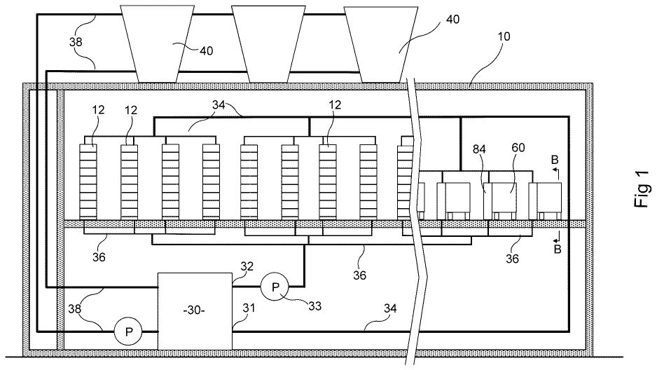

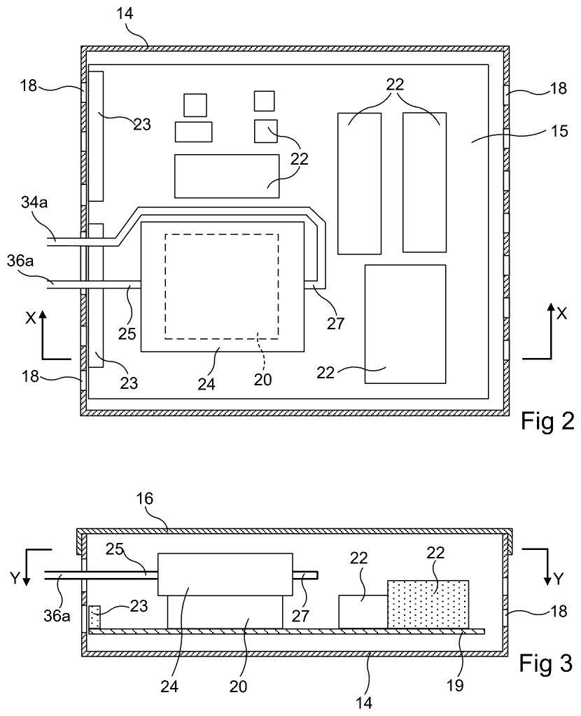

Embodiments of this disclosure will now be described by way of example. FIG. 1 is a diagrammatic representation of a two-storey building 10 which is a data center. One part of the building 10 contains a large number of racks 12 each of which contains a number of computing devices such as servers. One such computing device is shown schematically by FIGS. 2 and 3. It has an outer case 14 with a removable cover 16. Inside the case 14 is a printed circuit board 19 to which various electronic components are soldered. The components may include a CPU 20 or one or more GPUs as well as other components 22. The case 14 has openings 18 at opposite ends to allow air to flow through and also to allow electrical connections to connector blocks 23.

During operation, the CPU 20 emits heat. Cooling of the CPU is provided by a hollow vessel 24 which is made of metal such as copper or aluminium and is mounted in direct contact with the CPU 20 so as to allow heat emitted by the CPU to be conducted into the vessel 24. Coolant liquid is supplied to the vessel 24 at inlet 25 and leaves at outlet 27. Liquid cooled vessels mounted directly on a heat-emitting CPU or other electronic component are customarily referred to as “cold plates” but the vessel 24 has distinctive internal features further described below. Many or all of the numerous other computing devices in the racks 12 also have similar vessels 24 in them, to collect heat emitted from CPUs, GPUs and other components which emit heat during operation.

A cooling system connected to the numerous computing devices includes a heat exchanger 30, one side of which has an inlet 31 connected by a branching system of pipework 34 to the outlets 27 of the vessels 24. The outlet 32 of the heat exchanger 30 is connected to a pump 33 which propels coolant flow and is connected by a similar branching system of pipework 36 providing return flow to the vessels 24. The large heat exchanger 30 transfers heat energy in the flow from the vessels 24 to water flowing in another flow circuit 38 which carries the heat to cooling towers 40 on the roof of the data center 10.

The heat exchanger 30, the pipework systems 34, 36 and the vessels 24 are filled with a coolant liquid which may be an aqueous solution of a glycol. The branching systems of pipework 34, 36 may include pipes of various sizes and may also include components other than pipes. For example, the system 36 which carries flow from the heat exchanger 30 to the cold plates may include flow controlling valves and/or auxiliary pumps to control the proportions of flow in each of a number of pipes extending from a branch point.

The coolant liquid circulating from the vessels 24 to the heat exchanger 30 and returning to the vessels 24 contains a small percentage of a substance capable of causing elastic turbulence. This may be a long chain flexible polymer or a viscoelastic surfactant able to form worm-like micelles. The flow rate within a cold plate is at a rate where a Newtonian fluid would be in a state of laminar flow corresponding to a Reynolds number of 1000 or less.

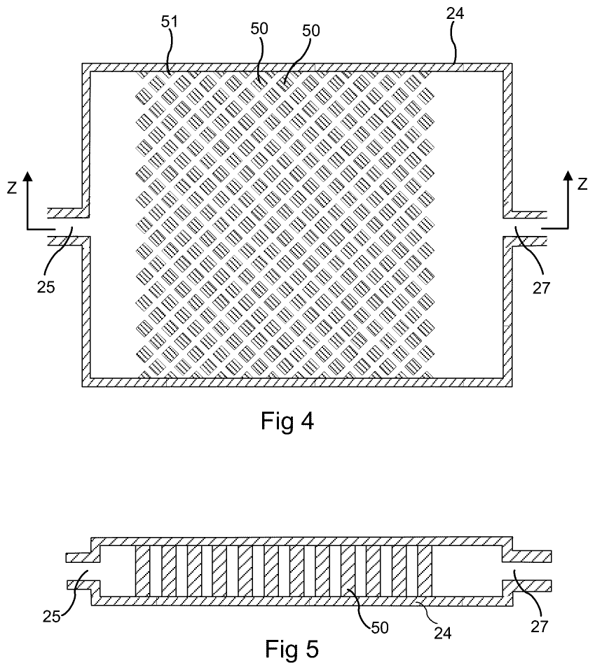

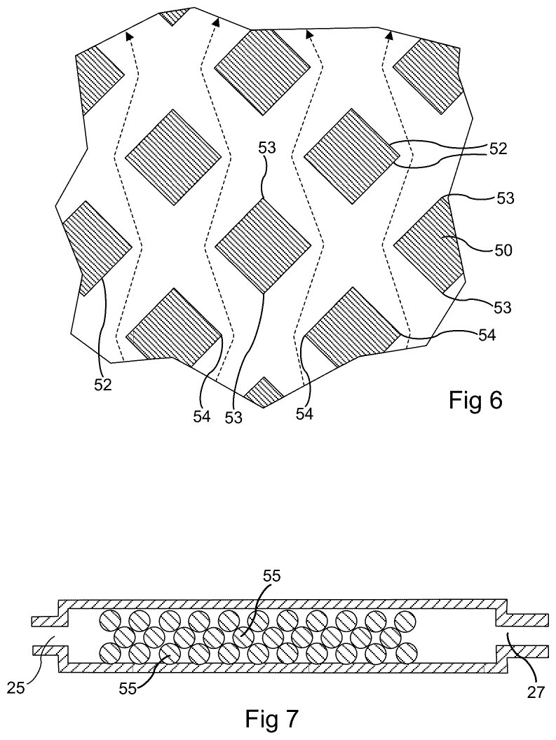

Internal structure within the vessel 24 is configured to compel flow through its interior to make a succession of changes of direction in order to induce elastic turbulence. As shown by FIG. 5, an array of pillars 50 extends across the interior of the vessel 24 from its face which is in direct contact with the CPU 20 to the opposite face. As shown by FIG. 4 and the enlargement which is FIG. 6, the pillars 50 have a square cross section with flat faces 52 meeting at corner edges 53 and 54. As shown in FIG. 4, the edges of the array are completed with pillars 51 which have a triangular cross section. Each pillar 50 is positioned so that the diagonal across the square cross section between corner edges 53 is aligned parallel to an imaginary line from the inlet 25 to the outlet 27. Thus the flat faces 52 of each pillar are inclined to the overall direction of flow. As shown by the enlarged view in FIG. 6, coolant liquid flows through the gaps between confronting edges 54 of adjacent pillars 50, but is then compelled to turn by another pillar. Thus the array of pillars 50 obstructs straight line flow from the inlet 25 to the outlet 27 and causes the streamlines of the flow indicated with broken lines in FIG. 6 to bend repeatedly.

The flow rate through the vessel 24 is arranged to be sufficient that the long chain polymer or worm-like micelles in the coolant liquid put that liquid in a state of elastic turbulence as it flows through the array of pillars. This has the effect of transferring heat energy from the metal of the vessel 24 to the coolant liquid more rapidly than would be transmitted by conduction under conditions of laminar flow without elastic turbulence.

FIG. 7 shows an alternative internal structure for a vessel 24. The interior of the plate contains a packing of spheres 55 made of the same metal as the outer parts of the cold plate. These spheres create tortuous paths for flow through the gaps between the spheres and so the flow through the vessel is compelled to change direction repeatedly.

A flow rate which is sufficient to cause elastic turbulence can be determined experimentally using pressure gauges to monitor the drop in pressure between the inlet and outlet of a cold plate as the flow rate is slowly increased. As the flow rate is increased from zero, the pressure drop will initially be directly proportional to the rate of flow, but when elastic turbulence begins, the ratio of pressure drop to flow rate will change and a graph of pressure drop against flow rate will show a change in slope.

The circulating coolant may be an emulsion or suspension in which the disperse phase is able to melt and to freeze at temperatures which are above the temperature at which the coolant liquid flows out of the heat exchanger 30 but below a maximum operating temperature for the electronic components which are being cooled by the circulating liquid. This will increase the heat carrying capacity of the circulating coolant liquid because melting of the disperse phase will require the latent heat of fusion of that phase in addition to heat to raise the temperature of the liquid.

As an illustration of this, if a circulating liquid is water and a unit mass of water with specific heat capacity cₚ^{water} is heated from temperature T₁ which is 25 °C to temperature T₂ which is 40 °C the enthalpy change is:

$$Δ {E}^{w a t e r} = {c}_{p}^{w a t e r} ( {T}_{2} - {T}_{1} )$$

A hypothetical circulating liquid is an emulsion with a continuous phase which is water and a disperse phase which is nonadecane melting to an oil at 33 °C. If unit mass of an emulsion containing proportion φ of the hydrocarbon is heated over the same temperature range, and the melting point of the hydrocarbon is between T₁ and T₂, the enthalpy change is

$$Δ {E}^{p c m} = ϕ ( {L}^{o i l} + {c}_{p}^{o i l} ( {T}_{2} - {T}_{1} ) ) + ( 1 - ϕ ) {c}_{p}^{w a t e r} ( {T}_{2} - {T}_{1} )$$

where L^{oil} is the latent heat of fusion of the hydrocarbon and for simplicity it is assumed that the specific heat of the hydrocarbon is the same for its frozen and liquid forms. In the case of an emulsion containing 32 vol % of nonadecane as the disperse phase in water as continuous phase, and with a temperature rise of 15° between T₁=25 °C and T₂=40 °C spanning the 33 °C melting temperature of the nonadecane, the calculated enthalpy change of the emulsion is approximately twice that of water alone.

Another part of the data centre building 10 contains computing equipment which is cooled by immersion in baths 60 of a non-conductive liquid, referred to as dielectric fluid. In accordance with the present disclosure, this fluid contains an additive enabling it to display elastic turbulence. For instance, the fluid may be a liquid hydrocarbon and the additive may be polyisobutane or 2,4-bis(2-ethylhexylureido) toluene (EHUT).

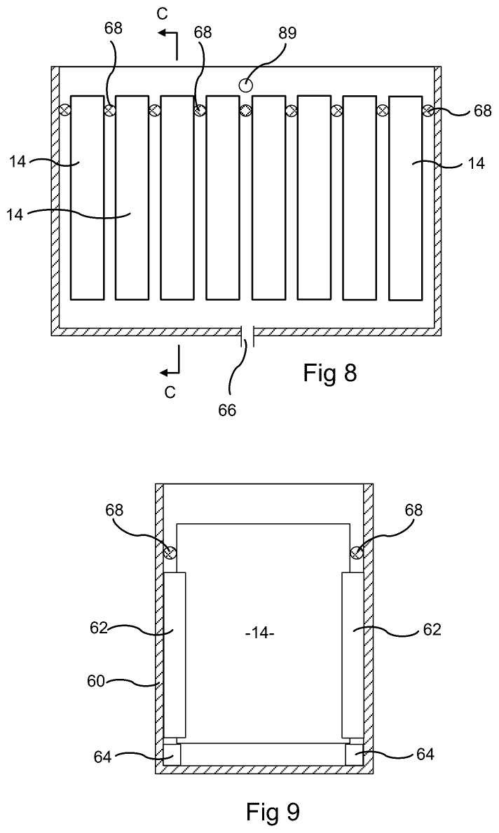

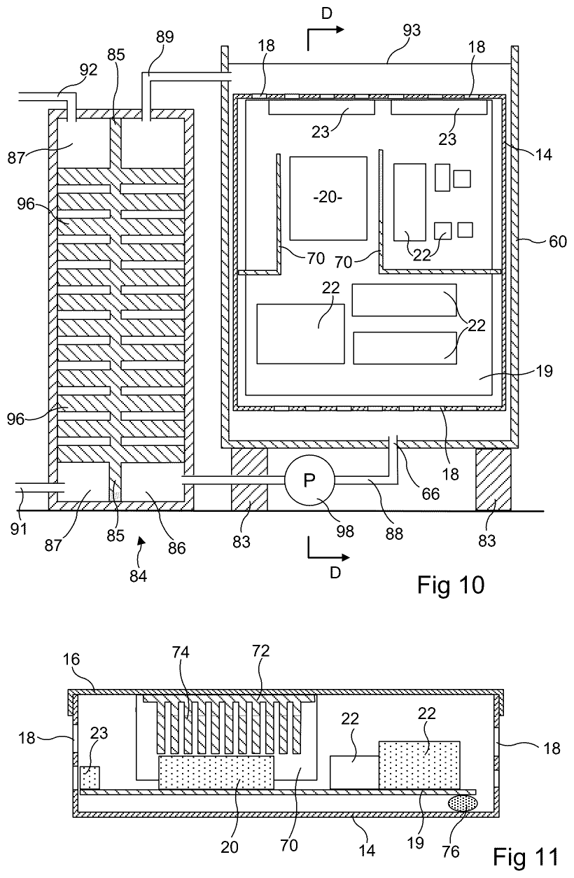

The position of the baths 60 is indicated in FIG. 1 and one bath is shown in more detail in FIGS. 8 to 11. As shown in FIGS. 9 and 10, computing devices with cases 14 are fitted into bath 60 from above. They fit between guides 62 and rest on supports 64 within the bath 60. The dielectric fluid is pumped into the bath 60 through bottom inlet 66. The fluid then flows upwardly into and through the computing devices. It enters and leaves through the holes 18 in the cases 14. Seals 68 between the individual computing devices and between these devices and the bath 60 prevent dielectric fluid from flowing upwardly outside the cases 14.

The bath 60 is raised on supports 83. Alongside it there is a heat exchanger 84 with a divider 85 between its two chambers 86, 87. This heat exchanger provides cooled dielectric fluid for the bath 60. The chamber 86 is connected to the bottom inlet 66 of the bath 60 by pipe 88 with a pump 98 to propel dielectric fluid from the chamber 86 to the bath 60. The surface of the dielectric fluid in the bath 60 is indicated at 93. Dielectric fluid flows back to the chamber 86 through pipe 89. The chamber 87 of the heat exchanger 84 has an inlet 91 connected to the pipework system 36 and an outlet 92 connected to the pipework system 34 and so coolant circulated by the pump 33 flows through this chamber 87 of the heat exchanger 84 to collect heat energy from the dielectric fluid flowing through the chamber 86.

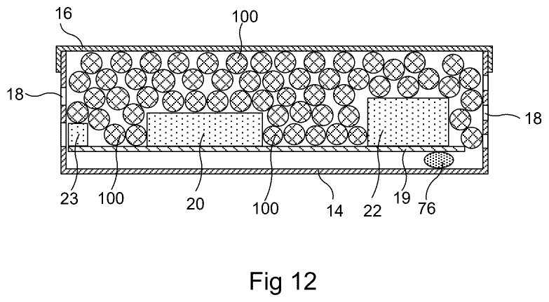

Within the bath 60, the dielectric fluid flows through each of the computing devices to cool the heat emitting components therein, which in this example is the CPU 20. FIGS. 11 and 12 shows an arrangement using elastic turbulence for assisting the transfer of heat energy from the CPU 20 to the flowing fluid. Attached to the case cover 16 are two guide members 70 extending from the cover 16 towards the circuit board 19, and these direct most of the dielectric fluid coming through the case 14 to flow over the CPU 20. A sealing strip 76 may be placed under the circuit board 19 as shown to reduce the amount of flow under the circuit board. Also attached to the cover 16 is a plate 72 with an array of square section pillars 74 extending from it towards the CPU 20 so that there is only a small gap between the extremities of the pillars 74 and the CPU 20. This array of pillars 74 is arranged similarly to the pillars 50 shown in FIGS. 4 and 6. Consequently the dielectric fluid flowing through this array of pillars is compelled to make a succession of changes of direction. The pumping power of the pump 98 is chosen such that the flow rate of the fluid through the array of pillars 74 is sufficient that the succession of changes in direction induce elastic turbulence in the flow between the pillars 74 and this also extends to the surface of the CPU 20, thereby improving the transfer of heat energy from the CPU to the flowing dielectric fluid.

Elastic turbulence is also used to enhance heat transfer at the heat exchanger 84. The divider 85 is made of a metal with good thermal conductivity, such as copper or aluminium, and at both sides it is integral with an array of pillars 96 of square cross section arranged similarly to the pillars 50 in FIGS. 4 and 6. Consequently, the liquids flowing through the chambers 86, 87 are both compelled to make a succession of changes of direction. Both of these liquids contain additives enabling them to display elastic turbulence. The flow rates through both chambers 86, 87 are made sufficient that the coolant in chamber 87 and the dielectric fluid in chamber 86 will both be in a state of elastic turbulence which improves heat transfer through the divider 85 and pillars 96 to the flowing coolant in chamber 87.

As mentioned above, the liquid which circulates through the pipework 34, 36 and the heat exchanger 30 may be an emulsion or suspension in which the disperse phase is able to melt and to freeze at temperatures which are above the temperature of cooled liquid flowing out of the heat exchanger 30 but below a maximum operating temperature for the electronic components which are being cooled by the circulating liquid.

The dielectric fluid may also be an emulsion or suspension of a substance able to melt or freeze at temperatures above the temperature of dielectric fluid from the heat exchanger chamber 26 but below a maximum operating temperature for the electronic components. One possibility for such an emulsion would be a fluorocarbon discontinuous phase in a hydrocarbon continuous phase, where the fluorocarbon melts to an oil at a temperature above 25 °C. A further possibility would be an emulsion of liposomes which have an insoluble phospholipid bilayer encapsulating a substance, which for the present case would be a substance with a melting temperature above 25 °C.

FIG. 12 shows a further possibility. No parts are attached to the cover 16 of the computing device. Instead, before the cover 16 is fitted to the case 14, the space above the circuit board 19 and attached electronic components is filled with a packing of spheres 100 (although other shapes could be used) so that paths of flow over the heat emitting components on the circuit board are tortuous. As above, an additive capable of causing elastic turbulence is present in the dielectric fluid and the flow over the heat emitting components is in a state of elastic turbulence, enhancing transfer of heat energy form the electronic components to the flowing dielectric fluid. The spheres may be a mixtures of sizes, so that random configurations are formed rather than a uniform packing.

The presence of the spheres 100 occupying otherwise empty space within the cases of each item of computing equipment also reduces the amount of dielectric fluid which is required to fill the bath 60. The spheres may be hollow with an empty interior, which will reduce their overall weight and this reduce the overall weight of the bath.

Various embodiments of this disclosure have been set out above. These are intended to assist understanding of this disclosure, but not to limit it in any way. It should be appreciated that any features or possibilities described in combination may, where it is practical to do so, be used individually. Also, features or possibilities mentioned in the following claims or described in any embodiment may be used in any other embodiment, in so far as it is practical to do so and where two or more of the following claims are dependent on the same preceding claim, the reader should understand that the present disclosure includes any possible combination of any two or more or all of those dependent claims with each other and also with that preceding claim.

1. Computing equipment comprising one or more circuit boards with one or more heat-emitting electronic components attached thereto together with a cooling system for the one or more heat-emitting electronic components, wherein the cooling system comprises:
a coolant liquid;
a flow circuit for the coolant liquid in which a path of liquid flow runs through a hollow vessel in thermal contact with the one or more heat-emitting electronic components or through a container within which the one or more heat-emitting electronic components are immersed in the circulating liquid; and
a pump to propel the coolant liquid around the flow circuit;
wherein the coolant liquid comprises, in solution therein, a substance enabling the coolant liquid to undergo elastic turbulence and the path of liquid flow through the hollow vessel or in contact with the one or more heat-emitting electronic components is configured to compel the flowing liquid to make repeated changes in direction.

2. The computing equipment of claim 1, wherein the coolant liquid comprises suspended particles of a substance which is insoluble in the coolant liquid and which has a melting temperature which is above 25 °C and below an operating temperature limit of the one or more heat-emitting electronic components.

3. The computing equipment of claim 2, wherein the suspended particles have a melting temperature in a range from 30 °C to 60 °C.

4. The computing equipment of claim 1, with the path of liquid flow running through the hollow vessel in thermal contact with the one or more heat emitting electronic components, wherein the hollow vessel has an interior chamber comprising a plurality of obstructions such that liquid flow through the interior chamber is repeatedly compelled to change direction and straight line flow through the interior chamber is not possible.

5. The computing equipment of claim 1, with the path of liquid flow running through a container within which the one or more heat emitting electronic components are immersed in the circulating liquid, wherein space around the circuit boards in the container is packed with objects having an average density lower than the density of the circulating liquid.

6. The computing equipment of claim 1, with the path of liquid flow running through a container within which the one or more heat emitting components are immersed in the circulating liquid, wherein space around the circuit boards in the container is packed with objects which compel flow of coolant liquid between the objects to make repeated changes of direction.

7. The computing equipment of claim 6, wherein the objects are hollow.

8. The computing equipment of claim 1, wherein the substance enabling the coolant liquid to display elastic turbulence is a linear polymer with a molecular weight of at least 106 Daltons.

9. The computing equipment of claim 1, wherein the substance enabling the coolant liquid to display elastic turbulence forms worm-like micelles in the coolant liquid.

10. A method of cooling one or more heat-emitting electronic components attached to one or more circuit boards, comprising:
circulating a coolant liquid through a hollow vessel in thermal contact with the one or more heat-emitting electronic components, or through a container within which the one or more heat-emitting electronic components are immersed in the circulating coolant liquid, wherein a path of liquid flow through the hollow vessel or in contact with the one or more heat-emitting electronic components is configured to compel the flowing liquid to make repeated changes in direction within the hollow vessel or adjacent to the immersed heat-emitting electronic components, wherein the coolant liquid comprises, in solution therein, a substance enabling the coolant liquid to undergo elastic turbulence; and
a rate of flow of the coolant liquid through the hollow vessel or adjacent to the heat-emitting electronic components is such that the flowing coolant liquid is in a state of elastic turbulence within the hollow vessel or in contact with the one or more heat-emitting electronic components.

11. The method of claim 10, wherein the coolant liquid comprises suspended particles of a substance which is insoluble in the coolant liquid and which has a melting temperature which is intermediate between temperature of the coolant liquid at the inlet and outlet of the hollow vessel.

12. The method of claim 11, wherein the suspended particles have a melting temperature in a range from 30 °C to 60 °C.

13. The method of claim 10, with the path of liquid flow running through the hollow vessel in thermal contact with the one or more heat-emitting electronic components, wherein the hollow vessel has an internal chamber with an array of obstructions extending across the internal chamber so that flow is repeatedly compelled to change direction.

14. The method of claim 10, with the path of liquid flow running through the container wherein the one or more heat-emitting electronic components are immersed in the circulating liquid, wherein space around the circuit boards in the container is packed with objects with an average density lower than the density of the circulating liquid.

15. The method of claim 10, with the path of liquid flow running through the container wherein the one or more heat-emitting electronic components are immersed in the circulating liquid, wherein space around the circuit boards in the container is packed with objects which compel flow of coolant liquid between the packed objects to make repeated changes of direction.

16. The method of claim 15, wherein the objects are hollow.

17. Computing equipment comprising one or more circuit boards with one or more heat-emitting electronic components attached thereto together with a cooling system for the one or more components, wherein the cooling system comprises:
a coolant liquid;
a container within which the one or more circuit boards and attached electronic components are immersed in circulating liquid;
a flow circuit for the coolant liquid in which a path of liquid flow runs through the container and adjacent to the immersed electronic components, and
a pump to propel coolant liquid around the flow circuit;
wherein space around the one or more circuit boards in the container is packed with objects with a density lower than the density of the coolant liquid and the coolant liquid comprises suspended particles of a substance which is insoluble in the coolant liquid and which has a melting point which is above 25 °C and below an operating temperature limit of the electronic components.

18. The computing equipment of claim 18, wherein the suspended particles have a melting temperature in a range from 30 °C to 60 °C.
